(19) United States
(12) Patent Application Publication
(10) Pub. No.: US 2024/0006354 A1
(43) Pub. Date: Jan. 4, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Shota OKABE, Tokyo (JP); Nozomi ITO, Tokyo (JP); Yuji TAKAHASHI, Tokyo (JP)

(21) Appl. No.: 18/190,460

(22) Filed: Mar. 27, 2023

(30) Foreign Application Priority Data
May 23, 2022 (JP) 2022-083565

(51) Int. Cl. H01L 23/00

(52) U.S. Cl. CPC H01L 24/05; H01L 24/03; H01L 24/48; H01L 24/43; H01L 2224/03464; H01L 2224/48664; H01L 2224/0345; H01L 2224/05124; H01L 2224/05644; H01L 2224/04042; H01L 2224/48639; H01L 2224/48644; H01L 2224/43826; H01L 2224/05147

(57) ABSTRACT

A semiconductor device includes a first metal film forming an uppermost layer wiring that has a bonding pad. A concentration of impurities at a crystal grain boundary of the first metal film is higher than a concentration of impurities in crystal grains in the first metal film. The maximum grain size of crystal grains included in the first metal film is less than 5 μm.

### CROSS-REFERENCE TO RELATED APPLICATIONS

The present application claims priority from Japanese Patent Application No. 2022-083565 filed on May 23, 2022, the content of which is hereby incorporated by reference to this application.

### BACKGROUND

The present disclosure relates to a semiconductor device and a method of manufacturing the same.

There are disclosed techniques listed below.
[Patent Document 1] Japanese Unexamined Patent Application Publication No. 2014-187073

For example, Patent Document 1 describes a semiconductor device. The semiconductor device disclosed in Patent Document 1 includes a wiring and an OPM (Over Pad Metallurgy) film. The wiring is an uppermost layer wiring. The wiring has a bonding pad(s). The wiring is made of an aluminum alloy. The OPM film is arranged on the bonding pad. A bonding wire is bonded to the bonding pad with the OPM film interposed therebetween.

### SUMMARY

However, in the semiconductor device disclosed in Patent Document 1, there is room for improvement in reliability of bonding between the bonding pad and the bonding wire. Other problems and novel features will become apparent from the description of the specification and the accompanying drawings.

A semiconductor device of the present disclosure includes a first metal film forming an uppermost layer wiring that has a bonding pad. A concentration of impurities at a crystal grain boundary of the first metal film is higher than a concentration of impurities in crystal grains in the first metal film. A maximum grain size of the crystal grains included in the first metal film is less than 5 μm.

The bonding reliability between the bonding pad and the bonding wire can be improved.

### BRIEF DESCRIPTION OF THE DRAWINGS

FIG. 1 is a sectional view of a semiconductor device DEV1.

FIG. 2 is a process drawing showing a method of manufacturing the semiconductor device DEV1.

FIG. 3 is a sectional view for explaining a sputtering step S1.

FIG. 4 is a sectional view for explaining a wiring patterning step S2.

FIG. 5 is a sectional view for explaining a protective film forming step S3.

FIG. 6 is a sectional view for explaining an OPM film forming step S4.

FIG. 7 is a sectional view of a semiconductor device DEV2.

FIG. 8 is a sectional view of a semiconductor device DEV3.

FIG. 9 is a sectional view of a semiconductor device DEV4.

### DETAILED DESCRIPTION

Embodiments of the present disclosure will be detailed with reference to the drawings.

### First Embodiment

A semiconductor device according to a first embodiment will be described. A semiconductor device according to the first embodiment is referred to as a semiconductor device DEV1.

<Configuration of Semiconductor Device DEV1>

A configuration of a semiconductor device DEV1 will be described below.

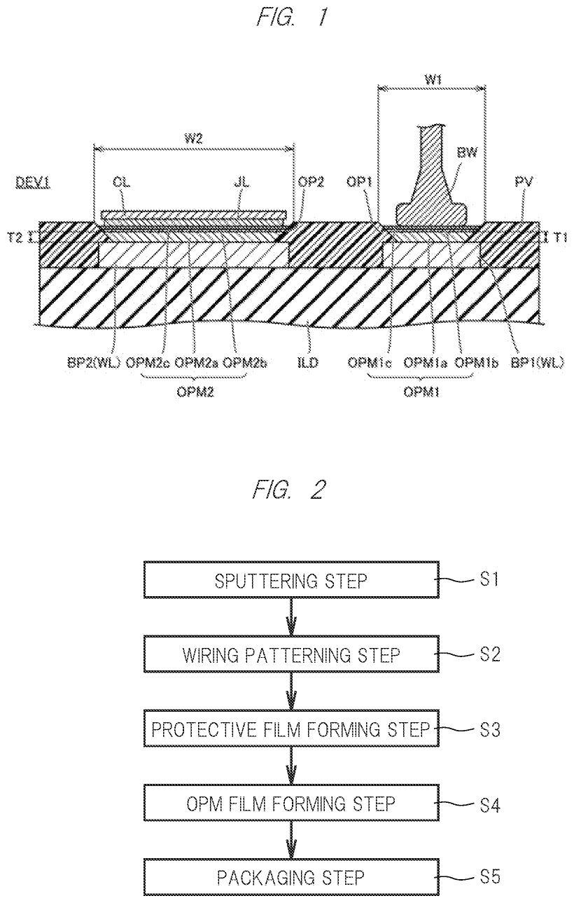

FIG. 1 is a sectional view of a semiconductor device DEV1. As shown in FIG. 1, the semiconductor device DEV1 includes an interlayer insulating film ILD, a wiring WL (first metal film), a protective film PV, an OPM film OPM1 (second metal film), and an OPM film OPM2. Incidentally, in FIG. 1, illustration of a structure below the interlayer insulating film ILD is omitted. The semiconductor device DEV1 is a power device. A specific example of the power device is an IGBT (Insulated Gate Bipolar Transistor). However, the semiconductor device DEV1 is not limited to an IGBT.

The interlayer insulating film ILD is the uppermost interlayer insulating film. The interlayer insulating film ILD is made of, for example, silicon oxide (SiO₂). The wiring WL is arranged on the interlayer insulating film ILD. The wiring WL is an uppermost layer wiring. The wiring WL has a bonding pad BP1 and a bonding pad BP2. When the semiconductor device DEV1 is an IGBT, the bonding pad BP1 and bonding pad BP2 are a gate electrode and an emitter electrode, respectively.

The wiring WL includes a first metal element as a main component. That is, a content of the first metal element in the wiring WL is 99% or more. The first metal element is, for example, aluminum (Al). The first metal element may be copper (Cu). The wiring WL2 may include a second metal element. When the first metal element is aluminum, the second metal element is, for example, at least one of silicon (Si), copper (Cu), and palladium (Pd).

The wiring WL includes impurities. These impurities are, for example, oxygen (O). These impurities may be nitrogen (N) or carbon (C). That is, the wiring WL may include at least one of oxygen, nitrogen, and carbon as impurities.

The wiring WL is polycrystalline. A concentration of impurities at a crystal grain boundary of the wiring WL is higher than a concentration of impurities in crystal grains of the wiring WL. When the impurities included in the wiring WL are oxygen, a concentration of oxygen in the crystal grains of the wiring WL is preferably 0.6 atomic % or more and 0.8 atomic % or less, and a concentration of oxygen in the crystal grain boundary of the wiring WL is preferably 0.9 atomic % or more and 1.5 atomic % or less.

The concentration of impurities at the crystal grain boundary of the wiring WL and the concentration of impurities in the crystal grains of the wiring WL are measured by using an EPMA (Electron Probe Micro Analyzer). A spot diameter of an electron beam when this measurement is performed is set to 1 μm or less. The concentration of impurities at the crystal grain boundary of the wiring WL and the concentration of impurities in the crystal grains of the wiring WL are measured at three measurement points, and its average value is calculated.

The maximum grain size of the crystal grains included in the wiring WL is less than 5 μm. The maximum grain size of the crystal grains included in the wiring WL is preferably less than 4 μm. The maximum value of the crystal grains included in the wiring WL is measured by an EBSD (Electron Back Scattered Electron) method. More specifically, first, an EBSD image is acquired in a cross-section of the wiring WL. This EBSD image has a magnification of 1500 times and a size of 50 μm×50 μm. Second, the crystal grain having the largest grain size in the EBSD images is identified, and a square root of a value obtained by dividing an area of the crystal grain by π/4 is calculated. This square root is regarded as the maximum grain size of the crystal grains included in the wiring WL.

Hardness of the wiring WL is preferably 0.8 GPa or more. The hardness of the wiring WL is measured by a nanoindentation hardness test specified in ISO14577. A test condition for this nanoindentation hardness test is that measurement temperature is room temperature, and an indentation depth of an indenter is about 10% of a thickness of the wiring WL. The hardness of the wiring WL is measured at 10 measurement points, and its average value is calculated.

The protective film PV is arranged on the interlayer insulating film ILD so as to cover the wiring WL. The protective film PV is made of polyimide, for example. An opening OP1 and an opening OP2 are formed in the protective film PV. The opening OP1 penetrates the protective film PV along a thickness direction. The bonding pad BP1 is exposed from the opening OP1. The opening OP2 penetrates the protective film PV along the thickness direction. The bonding pad BP2 is exposed from the opening OP2.

An opening width of the opening OP1 is referred to as a width W1. An opening width of the opening OP2 is referred to as a width W2. The width W1 is smaller than the width W2. The width W1 is preferably 300 μm or less. The width W1 is, for example, 90 μm or more. The width W2 is preferably 1000 μm or more. The width W2 is, for example, 10000 μm or less.

The OPM film OPM1 is arranged on the bonding pad BP1 exposed from the opening OP1. The OPM film OPM1 has, for example, an electroless nickel plating film OPM1a, an electroless palladium plating film OPM1b, and an electroless gold plating film OPM1c.

The electroless nickel plating film OPM1a is an electroless plating film (film formed by electroless plating) including nickel (Ni). The electroless nickel plating film OPM1a is arranged on the bonding pad BP1 exposed from the opening OP1.

The electroless palladium plating film OPM1b is an electroless plating film including palladium. The electroless palladium plating film OPM1b is arranged on the electroless nickel plating film OPM1a. The electroless gold plating film OPM1c is an electroless plating film including gold (Au). The electroless gold plating film OPM1c is arranged on the electroless palladium plating film OPM1b. The OPM film OPM1 may not have the electroless palladium plating film OPM1b. In this case, the electroless gold plating film OPM1c is arranged on the electroless nickel plating film OPM1a.

The OPM film OPM2 is arranged on the bonding pad BP2 exposed from the opening OP2. The OPM film OPM2 has the same film configuration as that of the OPM film OPM1. That is, the OPM film OPM2 has, for example, an electroless nickel plating film OPM2a, an electroless palladium plating film OPM2b, and an electroless gold plating film OPM2c. The electroless nickel plating film OPM2a is an electroless plating film including nickel.

The electroless nickel plating film OPM2a is arranged on the bonding pad BP2 exposed from the opening OP2. The electroless palladium plating film OPM2b is an electroless plating film including palladium. The electroless palladium plating film OPM2b is arranged on the electroless nickel plating film OPM2a. The electroless gold plating film OPM2c is an electroless plating film including gold. The electroless gold plating film OPM2c is arranged on the electroless palladium plating film OPM2b. The OPM film OPM2 may not have the electroless palladium plating film OPM2b. In this case, the electroless gold plating film OPM2c is arranged on the electroless nickel plating film OPM2a.

A thickness of the electroless nickel plating film OPM1a and a thickness of the electroless nickel plating film OPM2a are referred to as a thickness T1 and a thickness T2, respectively. The thickness T1 and the thickness T2 are, for example, 0.5 times or more the maximum grain size of crystal grains included in the wiring WL.

The semiconductor device DEV1 may further have a bonding wire BW, a clip CL, and a bonding layer JL.

The bonding wire BW includes a third metal element as a main component. That is, a content of the third metal element in the bonding wire BW is 99% by mass or more. The third metal element is any of aluminum, copper, silver (Ag), and gold. One end of the bonding wire BW is a ball portion. The bonding wire BW is bonded to the OPM film OPM1 at the ball portion. That is, the bonding wire BW is bonded to the bonding pad BP1 via the OPM film OPM1.

The clip CL is made of copper or a copper alloy, for example. The clip CL is bonded to the bonding pad BP2 by a bonding layer JL. The bonding layer JL is, for example, a solder alloy such as a tin (Sn) alloy. Although not shown, the bonding pad BP1 is electrically connected to a lead frame or the like via the bonding wires BW, and the bonding pad BP2 is electrically connected to the lead frame or the like via the clip CL and the joining layer JL.

<Method of Manufacturing Semiconductor Device DEV1>

A method of manufacturing the semiconductor device DEV1 will be described below.

FIG. 2 is a process drawing showing a method of manufacturing the semiconductor device DEV1. As shown in FIG. 2, the method of manufacturing the semiconductor device DEV1 includes a sputtering step S1, a wiring patterning step S2, a protective film forming step S3, an OPM film forming step S4, and a packaging step S5.

Prior to the sputtering step S1, the interlayer insulating film ILD and an underlying structure thereof are formed. Since the interlayer insulating film ILD and the underlying structure thereof are formed by a conventionally known method, a description thereof will be omitted here.

FIG. 3 is a sectional view for explaining a sputtering step S1. As shown in FIG. 3, in the sputtering step S1, a constituent material of the wiring WL is formed on the interlayer insulating film ILD. A sputtering gas used for this sputtering includes, for example, argon (Ar) gas and oxygen gas (O₂). Incidentally, when nitrogen is introduced into the wiring WL as impurities, nitrogen gas (N₂) is used instead of oxygen gas and when carbon is introduced into the wiring WL as impurities, gas including carbon (carbon monoxide (CO), methane (CH₄), etc.) is used. A content of oxygen gas in the sputtering gas is preferably 0.025 volume % or more and volume % or less.

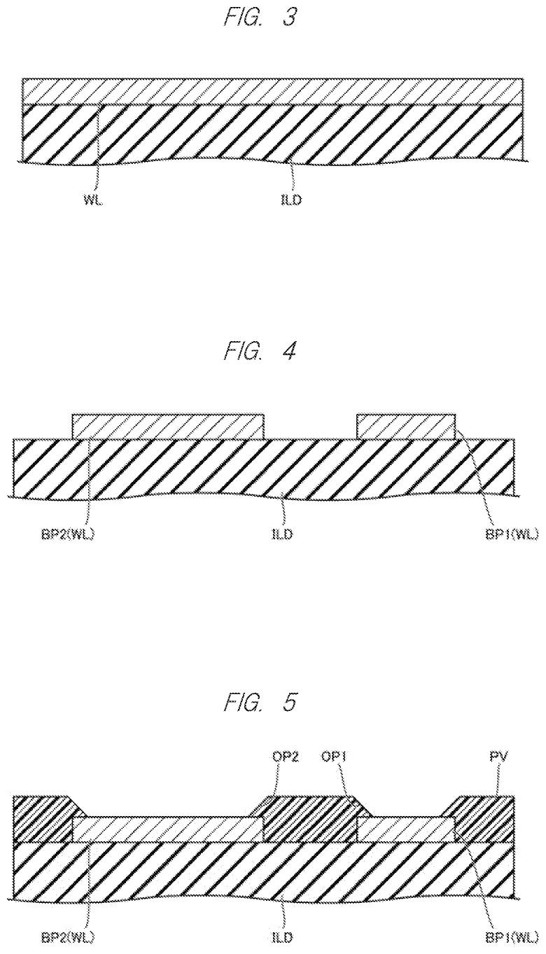

FIG. 4 is a sectional view for explaining a wiring patterning step S2. In the wiring patterning step S2, as shown in FIG. 4, the formed constituent material of the wiring WL in the sputtering step S1 is patterned. In the wiring patterning step S2, first, a resist pattern is formed on the formed constituent material of the wiring WL. This resist pattern is formed by exposing and developing a photoresist. Second, by using this resist pattern as a mask, the formed constituent material of the wiring WL is dry-etched. Consequently, the wiring WL having the bonding pad BP1 and the bonding pad BP2 is formed.

FIG. 5 is a sectional view for explaining a protective film forming step S3. As shown in FIG. 5, in the protective film forming step S3, a constituent material of the protective film PV is applied onto the interlayer insulating film ILD so as to cover the wiring WL. Secondly, the opening OP1 and the opening OP2 are formed by exposing and developing the applied constituent material of the protective film PV. Thirdly, the applied constituent material of the protective film PV is cured by heating to form a protective film PV.

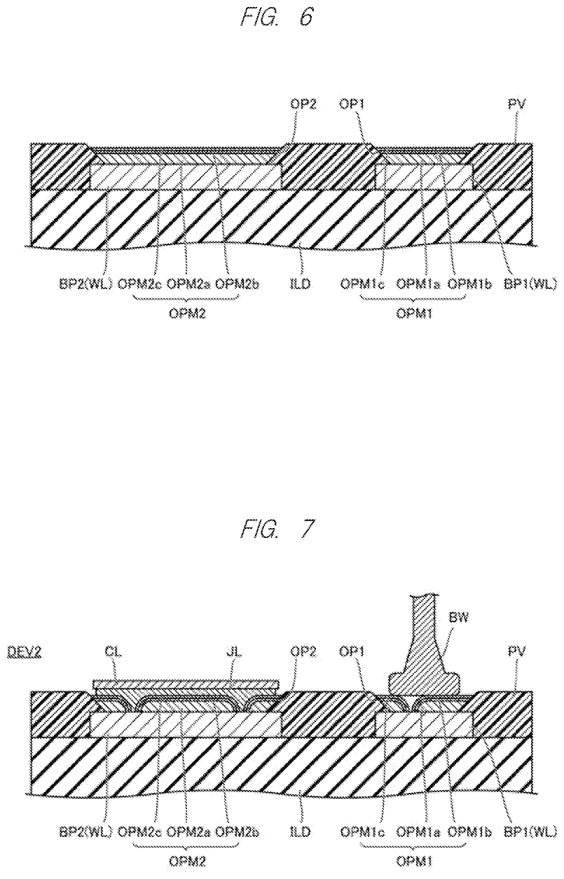

FIG. 6 is a sectional view for explaining an OPM film forming step S4. As shown in FIG. 6, in the OPM film forming step S4, an OPM film OPM1 and an OPM film OPM2 are formed on the bonding pad BP1 exposed from the opening OP1 and the bonding pad BP2 exposed from the opening OP2. The OPM film OPM1 and the OPM film OPM2 are formed by electroless plating, for example.

In the packaging step S5, the lead frame or the like and the OPM film OPM1 are connected by the bonding wire BW, and the lead frame or the like and the OPM film OPM2 are connected by the clip CL. Consequently, the semiconductor device DEV1 having the structure shown in FIG. 1 is formed.

<Effects of Semiconductor Device DEV1>

Effects of the semiconductor device DEV1 will be described below in comparison with a semiconductor device according to a comparative example. A semiconductor device according to a comparative example is referred to as a semiconductor device DEV2.

FIG. 7 is a sectional view of a semiconductor device DEV2. As shown in FIG. 7, the semiconductor device DEV2 has an interlayer insulating film ILD, a wiring WL, a protective film PV, an OPM film OPM1, and an OPM film OPM2. In the semiconductor device DEV2, the wiring WL has a bonding pad BP1 and a bonding pad BP2. In the semiconductor device DEV2, a concentration of oxygen at a crystal grain boundary of the wiring WL is approximately the same as the concentration of oxygen in a crystal grain of the wiring WL. Further, in the semiconductor device DEV2, the maximum grain size of the crystal grains included in the wiring WL is 5 μm or more (about 17 μm).

It is difficult to grow an electroless nickel plating film on a specific crystal plane of aluminum. Since the wiring WL is polycrystalline, such specific crystal planes may exist on a surface of the bonding pad BP1 and a surface of the bonding pad BP2. Even if such specific crystal planes exist on the surface of the bonding pad BP1 and the surface of the bonding pad BP2 and when the thickness T1 and the thickness T2 are set to 0.5 times or more of the maximum grain size of crystal grains included in the wiring WL, the electroless nickel plating film OPM1a and the electroless nickel plating film OPM2a grow laterally, so that the specific crystal planes lead to being covered with the electroless nickel plating film OPM1a and the electroless nickel plating film OPM2a.

In the semiconductor device DEV2, the crystal grains included in the wiring WL are coarsened by heating performed in the protective film forming step S3, for example, and the maximum grain size of the crystal grains included in the wiring WL, and the maximum grain size of the crystal grains included in the wiring WL is about 17 μm. Therefore, unless the thickness T1 and the thickness T2 are considerably increased (thickened), the electroless nickel plating film OPM1a and the electroless nickel plating film OPM2a are cracked, and the OPM film OPM1 and the OPM film OPM2 are cracked due to this cracking. A bonding wire BW is bonded to the bonding pad BP1 via the OPM film OPM1, but the bonding wire BW may be peeled off from the OPM film OPM1 starting from a crack in the OPM film OPM1. Thus, in the semiconductor device DEV2, there is room for improvement in the bonding reliability between the bonding wire BW and the bonding pad BP1.

Incidentally, also in the semiconductor device DEV2, by increasing the thickness T1 and the thickness T2, the specific crystal planes where the electroless nickel plating film OPM1a and the electroless nickel plating film OPM2a are difficult to grow can be covered with the electroless nickel plating film OPM1a and the electroless nickel plating film OPM2a. However, in this case, stresses due to the formation of the electroless nickel plating film OPM1a and the electroless nickel plating film OPM2a increase, and the semiconductor device DEV2 may warp. Moreover, in this case, manufacturing costs increase due to the formation of the electroless nickel plating film OPM1a and the electroless nickel plating film OPM2a.

In the semiconductor device DEV1, a small amount of oxygen gas is added to the sputtering gas in the sputtering step S1. Therefore, the crystal grain boundaries of the wiring WL are slightly oxidized, and the concentration of oxygen at the crystal grain boundaries of the wiring WL is higher than the concentration of oxygen in the crystal grains of the wiring WL. As a result, in the semiconductor device DEV1, even if heating is performed in the protective film forming step S3, mutual diffusion is suppressed by the oxidized crystal grain boundaries and, as a result, the crystal grains included in the wiring WL are less likely to coarsen and the maximum grain size of the crystal grains included in the wiring WL is less than 5 μm.

In order to confirm that coarsening of crystal grains included in the wiring WL is suppressed by making the concentration of oxygen at the crystal grain boundaries of the wiring WL higher than the concentration of oxygen in the crystal grains of the wiring WL, Sample 1 and Sample 2 were prepared. In Sample 1 and Sample 2, aluminum was sputtered to form the wiring WL. As shown in Table 1, in Sample 1, a content of oxygen gas in the sputtering gas was set to 0.05 volume %. On the other hand, for Sample 2, the sputtering gas included only argon and no oxygen gas. Sample 1 and Sample 2 were annealed at 400° C. for 30 minutes after the aluminum was sputtered.

TABLE 1

| | | SAMPLE 1 | SAMPLE 2 |
|---|---|---|---|
| SPUTTERING GAS | Ar FLOW (sccm) | 40 | 40 |
| | O2 FLOW (sccm) | 0.02 | — |
| | CONTENT OF O2 (VOLUME %) | 0.05 | — |
| OXYGEN | CRYSTAL GRAIN BOUNDARY (ATOMIC %) | 1.20 | 0.42 |
| CONCENTRATION | CRYSTAL GRAINS (ATOMIC %) | 0.68 | 0.48 |

| | | |
|---|---|---|
| MAXIMUM GRAIN SIZE OF CRYSTAL GRAINS(μm) | 3.56 | 16.84 |
| HARDNESS(GPa) | 0.87 | 0.58 |

In Sample 1, the concentration of oxygen at the crystal grain boundary of the aluminum film formed by sputtering was higher than the concentration of oxygen in the crystal grains of the aluminum film formed by sputtering. On the other hand, in Sample 2, the concentration of oxygen at the crystal grain boundary of the aluminum film formed by sputtering was lower than the concentration of oxygen in the crystal grains of the aluminum film formed by sputtering.

In Sample 1, the maximum grain size of the crystal grains included in the aluminum film formed by sputtering was 3.56 μm. On the other hand, in Sample 2, the maximum grain size of the crystal grains included in the aluminum film formed by sputtering was 16.84 μm. From this comparison, it is confirmed that coarsening of the crystal grains included in the wiring WL is suppressed when the concentration of oxygen at the crystal grain boundaries of the wiring WL is higher than the concentration of oxygen in the crystal grains of the wiring WL. Incidentally, in Sample 1, the hardness of the aluminum film formed by sputtering is higher than that in Sample 2 as a result of suppressing the coarsening of the crystal grains.

In the semiconductor device DEV1, the maximum grain size of the crystal grains included in the wiring WL is less than 5 μm, so that it is possible without increasing the thickness T1 and the thickness T2 to prevent the occurrence of cracking in the electroless nickel plating film OPM1a (OPM film OPM1) and the electroless nickel plating film OPM2a (OPM film OPM2) and eventually improve the bonding reliability between the bonding wire BW and the bonding pad BP1. Incidentally, even when the impurities included in the wiring WL are nitrogen or carbon, the nitrogen or carbon existing at the crystal grain boundary of the wiring WL suppresses the coarsening of the crystal grains included in the wiring WL, so that it is possible to improve the bonding reliability between the bonding wire BW and the bonding pad BP1 as with the above.

As the width W1 becomes smaller (more specifically, as the width W1 becomes 300 μm or less), a bonding area between the bonding wire BW and the OPM film OPM1 becomes smaller and the cracking existing in the OPM film OPM1 easily affects the bonding reliability. According to the semiconductor device DEV1, even if the width W1 is 300 μm or less, it is possible to improve the bonding reliability between the bonding wire BW and the bonding pad BP1.

### Second Embodiment

A semiconductor device according to a second embodiment will be described. A semiconductor device according to a second embodiment is referred to as a semiconductor device DEV3. Here, a difference(s) between the semiconductor device DEV3 and the semiconductor device DEV1 will be mainly described, and a redundant description will not be repeated.

<Configuration of Semiconductor Device DEV3>

A configuration of the semiconductor device DEV3 will be described below.

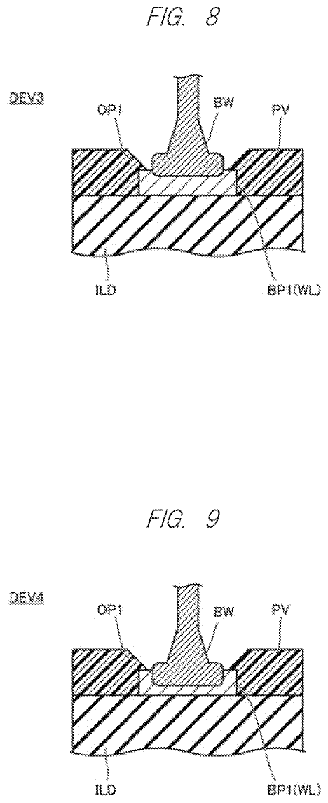

FIG. 8 is a sectional view of a semiconductor device DEV3. As shown in FIG. 8, a semiconductor device DEV3 has an interlayer insulating film ILD, a wiring WL, a protective film PV, and a bonding wire BW. In the semiconductor device DEV3, the wiring WL has a bonding pad BP1. In the semiconductor device DEV3, an opening OP1 is formed in the protective film PV. Regarding this point, a configuration of the semiconductor device DEV3 is common to the configuration of the semiconductor device DEV1.

In the semiconductor device DEV3, an OPM film OPM1 is not formed on the bonding pad BP1 exposed from the opening OP1. In the semiconductor device DEV3, the bonding wire BW is directly bonded to the bonding pad BP1. Regarding these points, the configuration of the semiconductor device DEV3 is different from the configuration of the semiconductor device DEV1. Incidentally, the semiconductor device DEV3 is, for example, an LSI (Large Scale Integrated circuit).

<Effects of Semiconductor Device DEV3>

Effects of the semiconductor device DEV3 will be described below in comparison with a semiconductor device according to a comparative example. The semiconductor device according to the comparative example is referred to as a semiconductor device DEV4.

FIG. 9 is a sectional view of a semiconductor device DEV4. As shown in FIG. 9, a semiconductor device DEV4 has an interlayer insulating film ILD, a wiring WL, a protective film PV, and a bonding wire BW. In the semiconductor device DEV4, the wiring WL has the bonding pad BP1. In the semiconductor device DEV4, an opening OP1 is formed in the protective film PV. In the semiconductor device DEV4, the OPM film OPM1 is not formed on the bonding pad BP1 exposed from the opening OP1. In the semiconductor device DEV4, the bonding wire BW is directly bonded to the bonding pad BP1.

However, in the semiconductor device DEV4, the concentration of impurities at the crystal grain boundary of the wiring WL is not higher than the concentration of impurities in the crystal grains of the wiring WL. As a result, in the semiconductor device DEV4, the maximum grain size of crystal grains included in the wiring WL is 5 μm or more, and the hardness of the wiring WL is low. Therefore, in the semiconductor device DEV4, the wire WL is deformed due to wire bonding, a thickness of the bonding pad BP1 directly under the bonding wire BW is reduced, and cracks are likely to occur in the bonding pad BP1. Such cracks cause a decrease in bonding reliability between the bonding pad BP1 and the bonding wire BW.

On the other hand, in the semiconductor device DEV3, the maximum grain size of crystal grains included in the wiring WL is less than 5 μm, and the hardness of the wiring WL is high. Therefore, in the semiconductor device DEV3, by suppressing the deformation of the wiring WL due to wire bonding, and it is possible to suppress a reduction in thickness of the bonding pad BP1 directly under the bonding wire BW and eventually suppress the occurrence of the cracking of the bonding pad BP1. Therefore, according to the semiconductor device DEV3, the bonding reliability between the bonding wire BW and the bonding pad BP1 can be improved.

The invention made by the present inventors has been specifically described above based on the embodiments, but the present invention is not limited to the above-described embodiments and, needless to say, can variously be modified made without departing from the scope of the invention.

What is claimed is:

1. A semiconductor device comprising:
a first metal film forming an uppermost layer wiring having a bonding pad,
wherein a concentration of impurities at a crystal grain boundary of the first metal film is higher than a concentration of impurities in crystal grains of the first metal film, and
wherein a maximum grain size of the crystal grains included in the first metal film is less than 5 μm.

2. The semiconductor device according to claim 1,
wherein the first metal film includes a first metal element,
wherein a content of the first metal element in the first metal film is 99% by mass or more, and
wherein the first metal element is aluminum or copper.

3. The semiconductor device according to claim 2,
wherein the first metal element is aluminum,
wherein the first metal film further includes a second metal element, and
wherein the second metal element is at least one of copper, silicon, and palladium.

4. The semiconductor device according to claim 1,
wherein the impurities are at least one of oxygen, nitrogen, and carbon.

5. The semiconductor device according to claim 1,
wherein the impurities are oxygen,
wherein a concentration of oxygen in the crystal grains of the first metal film is 0.6 atomic % or more and 0.8 atomic % or less,
wherein a concentration of oxygen at the crystal grain boundary of the first metal film is 0.9 atomic % or more and 1.5 atomic % or less.

6. The semiconductor device according to claim 1, comprising a second metal film arranged on the bonding pad.

7. The semiconductor device according to claim 6,
wherein the second metal film is an electroless plating film.

8. The semiconductor device according to claim 7, wherein the second metal film includes a first film arranged on the bonding pad, and
wherein the first film is an electroless nickel plating film.

9. The semiconductor device according to claim 8,
wherein the second metal film further includes a second film arranged on the first film, and
wherein the second film is an electroless gold plating film.

10. The semiconductor device according to claim 8,
wherein the second metal film further includes a second film arranged on the first film and a third film arranged on the second film,
wherein the second film is an electroless palladium plating film, and
wherein the third film is an electroless gold plating film.

11. The semiconductor device according to claim 8, comprising a bonding wire,
wherein the bonding wire is bonded to the second metal film.

12. The semiconductor device according to claim 11,
wherein the bonding wire includes a third metal element,
wherein a content of the third metal element in the bonding wire is 99% by mass or more, and
wherein the third metal element is any one of aluminum, copper, silver, and gold.

13. The semiconductor device according to claim 1, comprising a bonding wire,
wherein the bonding wire is bonded to the bonding pad.

14. The semiconductor device according to claim 1,
wherein hardness of the first metal film is 0.8 GPa or more.

15. The semiconductor device according to claim 1, comprising a protective film covering the first metal film,
wherein an opening is formed in the protective film to expose the bonding pad, and
wherein a width of the opening is 300 μm or less.

16. A method of manufacturing a semiconductor device, the method comprising:
forming a first metal film by sputtering; and
forming an uppermost layer wiring by patterning the first metal film, the uppermost layer wiring having a bonding pad,
wherein when the sputtering is performed, oxygen gas is added to sputtering gas.

17. The method according to claim 16,
wherein a content of the oxygen gas in the sputtering gas is 0.025 volume % or more and 0.25 volume % or less.
